(19) United States
(12) Patent Application Publication
(10) Pub. No.: US 2015/0346254 A1
(43) Pub. Date: Dec. 3, 2015

(54) NOISE IMMUNITY EVALUATION APPARATUS, METHOD OF EVALUATING NOISE IMMUNITY, AND NON-TRANSITORY COMPUTER READABLE MEDIUM

(71) Applicant: FUJI XEROX CO., LTD., Tokyo (JP)

(72) Inventor: Shigeo NARA, Yokohama-shi (JP)

(73) Assignee: FUJI XEROX CO., LTD., Tokyo (JP)

(21) Appl. No.: 14/538,902

(22) Filed: Nov. 12, 2014

(30) Foreign Application Priority Data
May 28, 2014 (JP) 2014-110682

(51) Int. Cl. G01R 29/08; G01R 29/26

(52) U.S. Cl. CPC G01R 29/0835; G01R 29/26

(57) ABSTRACT

A noise immunity evaluation apparatus measures S parameters of a device including a pair of input signal ports, a pair of output signal ports, and a noise signal port for input of a noise signal; calculates, as an evaluation index, a difference between S parameters between the noise signal port and the pair of input signal ports or between the noise signal port and the pair of output signal ports; acquires a first frequency spectrum obtained by performing a fast Fourier transform on a voltage waveform obtained by performing an electromagnetic field analysis on the noise signal, and calculates a second frequency spectrum as a product of the first frequency spectrum and the evaluation index; and extracts a frequency with a local maximum voltage value in the second frequency spectrum as a frequency for evaluation of noise immunity.

### CROSS-REFERENCE TO RELATED APPLICATIONS

This application is based on and claims priority under 35 USC 119 from Japanese Patent Application No. 2014-110682 filed May 28, 2014.

### BACKGROUND

(i) Technical Field

The present invention relates to a noise immunity evaluation apparatus, a method of evaluating noise immunity, and a non-transitory computer readable medium.

(ii) Related Art

The noise immunity of an electronic device or the like is occasionally evaluated through an electromagnetic field analysis performed using a noise signal that simulates the characteristics of an electrostatic discharge (ESD) gun. In this method, a voltage waveform of a voltage induced in the electronic device or the like is obtained through an electromagnetic field analysis, and a frequency at which a voltage peak (local maximum value) appears in a frequency spectrum obtained by performing a fast Fourier analysis on the voltage waveform is extracted as the frequency of a noise signal that affects the electronic device or the like.

### SUMMARY

According to an aspect of the present invention, there is provided a noise immunity evaluation apparatus including: an S parameter measurement section that measures S parameters of a device under test that includes at least a pair of input signal ports, a pair of output signal ports, and a noise signal port for input of a noise signal; an evaluation index calculation section that calculates, as an evaluation index, a difference between S parameters, among the S parameters, between the noise signal port and the pair of input signal ports or a difference between S parameters, among the S parameters, between the noise signal port and the pair of output signal ports; a second frequency spectrum calculation section that acquires a first frequency spectrum obtained by performing a fast Fourier transform on a voltage waveform obtained by performing an electromagnetic field analysis on the noise signal input to the noise signal port, and that calculates a second frequency spectrum as a product of the first frequency spectrum and the evaluation index; and a frequency extraction section that extracts a frequency at which a voltage reaches a local maximum value in the second frequency spectrum as a frequency at which noise immunity is evaluated.

### BRIEF DESCRIPTION OF THE DRAWINGS

Exemplary embodiments of the present invention will be described in detail based on the following figures, wherein:

FIGS. 1A to 1C illustrate an overview of a method of evaluating the noise immunity of an electronic device using an electrostatic discharge (ESD) gun, in which FIG. 1A illustrates an evaluation method in which the ESD gun is used, FIG. 1B illustrates a current waveform prescribed by the international standard IEC 61000-4-2 to test noise due to electrostatic discharge from a human body, and FIG. 1C illustrates a voltage waveform used to obtain noise immunity through an electromagnetic field analysis;

FIG. 2 illustrates the configuration of a noise immunity evaluation apparatus according to a first exemplary embodiment;

FIG. 3 is a functional block diagram of the noise immunity evaluation apparatus;

FIG. 4 illustrates a device under test (DUT) including a differential cable;

FIGS. 5A to 5C each illustrate a connection diagram and an S matrix for a case where an S matrix for a device under test with five ports is measured using a network analyzer (NA) with five ports, in which FIG. 5A corresponds to a case where a current clamp is provided at a position of a differential cable 310 close to a transmission section, FIG. 5B corresponds to a case where the current clamp is provided at the center portion of the differential cable 310, and FIG. 5C corresponds to a case where the current clamp is provided at a position of the differential cable 310 close to a reception section;

FIGS. 6A to 6C each illustrate a connection diagram, a measurement S matrix, and a target S matrix (L) for a case where a target S matrix (L) is measured using an NA with four ports, in which FIG. 6A corresponds to a measurement 1, FIG. 6B corresponds to a measurement 2, and FIG. 6C corresponds to a measurement 3;

FIGS. 7A and 7B each illustrate a connection diagram, a measurement S matrix, and a target S matrix (C) for a case where a target S matrix (C) is measured using an NA with four ports, in which FIG. 7A corresponds to a measurement 2 and FIG. 7B corresponds to a measurement 3;

FIGS. 8A and 8B each illustrate a connection diagram, a measurement S matrix, and a target S matrix (R) for a case where a target S matrix (R) is measured using an NA with four ports, in which FIG. 8A corresponds to a measurement 2 and FIG. 8B corresponds to a measurement 3;

FIG. 9A illustrates a voltage waveform of a voltage induced on the reception section side of the differential cable through discharge by the ESD gun, and FIG. 9B illustrates a fast Fourier transform (FFT) frequency spectrum obtained by performing an FFT on the voltage waveform;

FIGS. 10A to 10C illustrate a method of extracting a frequency at which a transient analysis is performed according to the first exemplary embodiment, the method being applied to a cable A, in which FIG. 10A illustrates an FFT frequency spectrum obtained through an electromagnetic field analysis, FIG. 10B illustrates an evaluation index (|S53−S54|), and FIG. 10C illustrates a product frequency spectrum which is the product of the FFT frequency spectrum of FIG. 10A and the evaluation index (|S53−S54|) of FIG. 10B;

FIGS. 11A to 11C each illustrate an eye pattern, at the reception section, of a signal obtained through a transient analysis at 154 MHz for the cable A, in which FIG. 11A corresponds to a noise signal voltage of 5 V, FIG. 11B corresponds to a noise signal voltage of 10 V, and FIG. 11C corresponds to a noise signal voltage of 20 V;

FIGS. 12A to 12C each illustrate an eye pattern, at the reception section, of a signal obtained through a transient analysis at 223 MHz for the cable A, in which FIG. 12A corresponds to a noise signal voltage of 5 V, FIG. 12B corresponds to a noise signal voltage of 10 V, and FIG. 12C corresponds to a noise signal voltage of 20 V;

FIGS. 13A to 13C each illustrate an eye pattern, at the reception section, of a signal obtained through a transient analysis at 633 MHz for the cable A, in which FIG. 13A corresponds to a noise signal voltage of 5 V, FIG. 13B corresponds to a noise signal voltage of 10 V, and FIG. 13C corresponds to a noise signal voltage of 20 V;

FIGS. 14A to 14C each illustrate an eye pattern, at the reception section, of a signal obtained through a transient analysis at 644 MHz for the cable A, in which FIG. 14A corresponds to a noise signal voltage of 5 V, FIG. 14B corresponds to a noise signal voltage of 10 V, and FIG. 14C corresponds to a noise signal voltage of 20 V;

FIGS. 15A to 15C illustrate a method of extracting a frequency at which a transient analysis is performed according to the first exemplary embodiment, the method being applied to a cable B, in which FIG. 15A illustrates an FFT frequency spectrum obtained through an electromagnetic field analysis, FIG. 15B illustrates an evaluation index (|S53−S54|), and FIG. 15C illustrates a product frequency spectrum which is the product of the FFT frequency spectrum of FIG. 15A and the evaluation index (|S53−S54|) of FIG. 15B;

FIG. 16 is a flowchart of a method of evaluating noise immunity according to the first exemplary embodiment;

FIGS. 17A to 17C each illustrate an eye pattern, at the reception section, of a signal obtained through a transient analysis at 154 MHz for the cable B, in which FIG. 17A corresponds to a noise signal voltage of 5 V, FIG. 17B corresponds to a noise signal voltage of 10 V, and FIG. 17C corresponds to a noise signal voltage of 20 V;

FIGS. 18A to 18C each illustrate an eye pattern, at the reception section, of a signal obtained through a transient analysis at 644 MHz for the cable B, in which FIG. 18A corresponds to a noise signal voltage of 5 V, FIG. 18B corresponds to a noise signal voltage of 10 V, and FIG. 18C corresponds to a noise signal voltage of 20 V;

FIGS. 19A and 19B illustrate estimations based on ESD immunity tests, evaluations based on eye patterns, estimations based on product frequency spectra, and coincidence between the estimations and the evaluations, in which FIG. 19A illustrates estimations based on ESD immunity tests, evaluations based on eye patterns, and coincidence between the estimations and the evaluations, and FIG. 19B illustrates estimations based on product frequency spectra, evaluations based on eye patterns, and coincidence between the estimations and the evaluations; and

FIG. 20 is a flowchart of a method of evaluating noise immunity according to a second exemplary embodiment.

### DETAILED DESCRIPTION

Exemplary embodiments of the present invention will be described below with reference to the accompanying drawings.

### First Exemplary Embodiment

### Noise Immunity

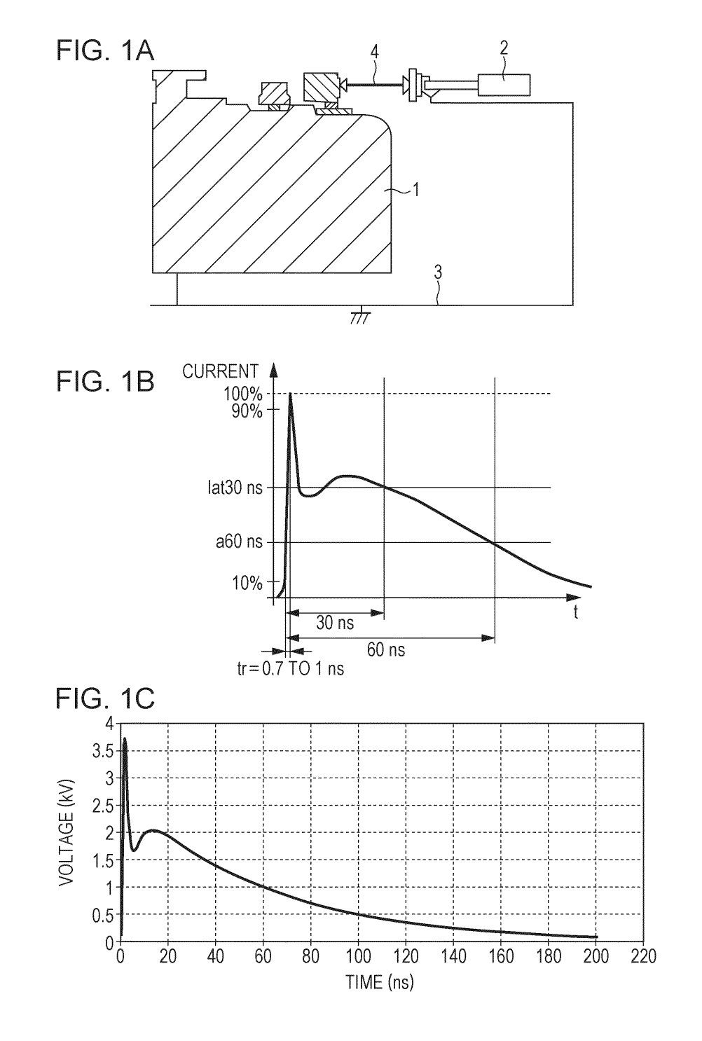

FIGS. 1A to 1C illustrate an overview of a method of evaluating the noise immunity of an electronic device 1 using an electrostatic discharge (ESD) gun 2. FIG. 1A illustrates an evaluation method in which the ESD gun 2 is used. FIG. 1B illustrates a current waveform prescribed by the international standard IEC 61000-4-2 to test noise due to electrostatic discharge from a human body. FIG. 1C illustrates a voltage waveform used to obtain noise immunity through an electromagnetic field analysis. In FIG. 1B, the vertical axis represents the current, and the horizontal axis represents the time. In FIG. 1C, the vertical axis represents the voltage, and the horizontal axis represents the time.

Noise immunity evaluation refers to evaluation of resistance (immunity) to noise that invades the electronic device 1 from the outside of the electronic device 1. The noise immunity evaluation is also called an “immunity test”.

A method of evaluating noise immunity using the ESD gun 2 will be described. Evaluation of noise immunity performed using the ESD gun 2 may occasionally be called a “noise immunity test”.

As illustrated in FIG. 1A, in the case where an image forming apparatus is the electronic device 1, for example, a common ground wire 3 is provided, and the ESD gun 2 generates discharge 4 for a housing of the electronic device 1 (image forming apparatus). Then, the effect of noise induced in an electronic circuit or the like in the electronic device 1 by the discharge 4 is evaluated. In general, this method is used for a completed electronic device 1 (actual device). Here, a case where a simulation is performed through an electromagnetic field analysis will be described. Since discharge is generated for the electronic device 1, an expression “ESD housing analysis” is used.

The discharge 4 generated by the ESD gun 2 has a waveform that matches a current waveform prescribed by the international standard IEC 61000-4-2 illustrated in FIG. 1B. That is, according to the international standard IEC 61000-4-2, the current I takes 0.7 nsec to 1 nsec to rise from 10% of the peak to the peak. The current I is represented by a pulse waveform that rises in a short period.

To evaluate noise immunity using the ESD gun 2, it is necessary to prepare the electronic device 1 (actual device). Hence, noise immunity may be evaluated through a simulation.

FIG. 1C illustrates a voltage waveform used to obtain noise immunity through an electromagnetic field analysis, which is set along the current waveform prescribed by the international standard IEC 61000-4-2. If an electromagnetic field analysis is performed using the voltage waveform, ESD immunity may be evaluated through a simulation before the electronic device 1 (actual device) is completed.

(Configuration of Noise Immunity Evaluation Apparatus 100)

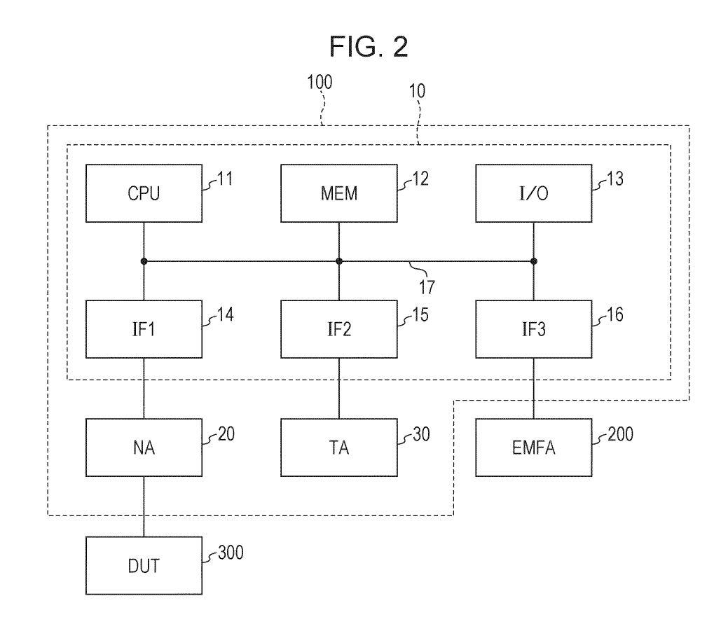

FIG. 2 illustrates the configuration of a noise immunity evaluation apparatus 100 according to a first exemplary embodiment.

Evaluation of noise immunity is performed by a combination of the noise immunity evaluation apparatus 100 and an electromagnetic field analyzer (hereinafter denoted as an “EMFA”) 200.

The EMFA 200 simulates the effect of discharge from the ESD gun 2 on the basis of design data on the electronic device 1. That is, a voltage waveform induced in a state similar to the generation of discharge from the ESD gun 2 is calculated. Then, the voltage waveform is subjected to a fast Fourier transform (hereinafter denoted as an “FFT”) to be converted into a frequency spectrum (denoted as an “FFT frequency spectrum”, which is an example of a first frequency spectrum).

The EMFA 200 is an example of an electromagnetic field analysis section.

As indicated as surrounded by a broken line in FIG. 2, the noise immunity evaluation apparatus 100 includes a computation device 10 such as a personal computer (PC), a network analyzer (hereinafter denoted as an “NA”) 20, and a transient analyzer (hereinafter denoted as a “TA”) 30.

A device under test (hereinafter denoted as a “DUT”) 300 is connected to the NA 20 so that the NA 20 measures S parameters of the DUT 300. As discussed later, a matrix of S parameters corresponding to ports of the DUT 300 is called an “S matrix”.

The TA 30 performs a transient analysis on a signal at a designated frequency, and simulates a waveform (a signal waveform, and an eye pattern to be discussed later) propagated in the DUT 300, that is, transient characteristics.

In the case where the NA 20 has the function of the TA 30, it is not necessary to separately provide the TA 30. In the case where evaluation is performed without performing a transient analysis as described in relation to a second exemplary embodiment to be discussed later, the noise immunity evaluation apparatus 100 may not include the TA 30.

The computation device 10 includes a central processing unit (hereinafter denoted as a “CPU”) 11, a memory (hereinafter denoted a “MEM”) 12, an input/output device (hereinafter denoted as an “I/O”) 13, and interfaces (hereinafter denoted as “IFs”) 14 to 16.

The CPU 11, the MEM 12, the I/O 13, and the IFs 14 to 16 are connected to each other through a signal bus 17.

In FIG. 2, the NA 20 is connected to the IF 14, the TA 30 is connected to the IF 15, and the EMFA 200 is connected to the IF 16.

The CPU 11 includes an arithmetic logical unit (ALU) that executes logical operations and arithmetic operations.

The MEM 12 is composed of a random access memory (RAM), a read only memory (ROM), a hard disk drive (HDD), and so forth, and stores a program and data for executing the logical operations and the arithmetic operations performed by the CPU 11.

The I/O 13 includes an output device, such as a display, that displays information related to the state of the noise immunity evaluation apparatus 100, and an input device, such as a keyboard, a touch panel, and/or a button, that allows a user to provide an instruction to the noise immunity evaluation apparatus 100.

The IFs 14 to 16 are each a serial or parallel interface that exchanges data with the device (the NA 20, the TA 30, or the EMFA 200) connected thereto.

The CPU 11 of the computation device 10 reads the program and the data stored in the MEM 12, and executes the program. Then, the NA 20, the TA 30, or the EMFA 200 receives the processed data via one of the IFs 14 to 16, performs a computation determined in advance, and stores the computation results in the MEM 12 or transmits the computation results to the I/O 13. Further, the CPU 11 transmits the computation results to the NA 20, the TA 30, or the EMFA 200 via one of the IFs 14 to 16, and provides the NA 20, the TA 30, or the EMFA 200 with an instruction to execute a process.

The EMFA 200 also has a configuration similar to that of the computation device 10. Hence, the noise immunity evaluation apparatus 100 may include the function of the EMFA 200.

(Functional Blocks of Noise Immunity Evaluation Apparatus 100)

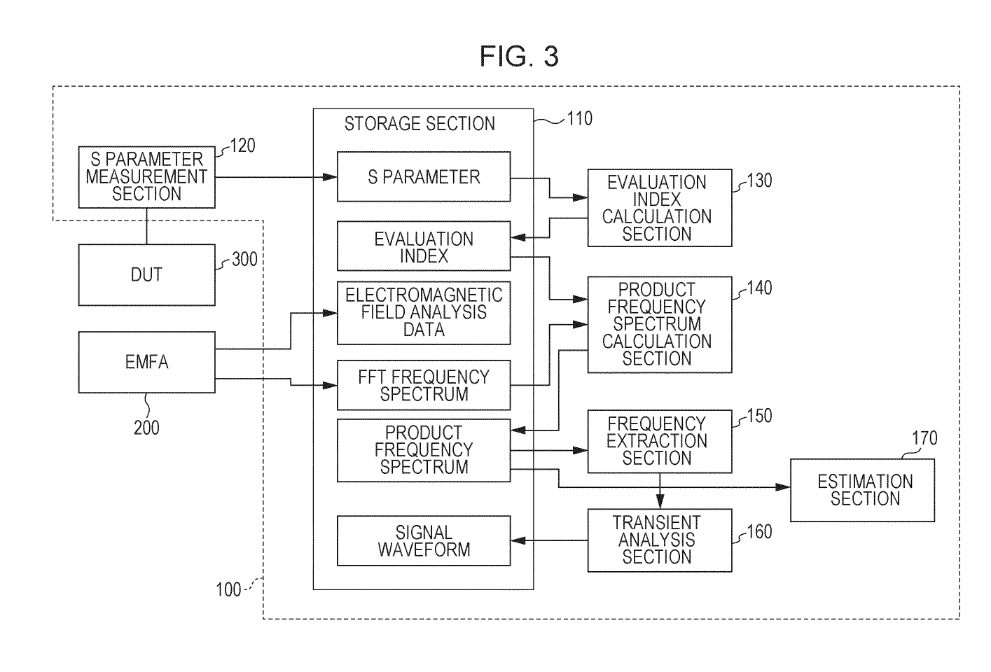

FIG. 3 is a functional block diagram of the noise immunity evaluation apparatus 100. In the drawing, the EMFA 200 and the DUT 300 are also illustrated besides the noise immunity evaluation apparatus 100.

The noise immunity evaluation apparatus 100 includes a storage section 110 that stores various data to be discussed later, an S parameter measurement section 120 that measures S parameters (an S matrix to be discussed later; the S parameters are elements of the S matrix) of the DUT 300, and an evaluation index calculation section 130 that calculates a difference (evaluation index) between S parameters determined in advance. The S parameters and the evaluation index are stored in the storage section 110.

Further, the noise immunity evaluation apparatus 100 acquires, from the EMFA 200, a voltage waveform (electromagnetic field analysis data) obtained through an electromagnetic field analysis when noise is input and an FFT frequency spectrum obtained by performing an FFT on the electromagnetic field analysis data, and stores the acquired data and FFT frequency spectrum in the storage section 110.

The noise immunity evaluation apparatus 100 also includes a product frequency spectrum calculation section 140, which is an example of a second frequency spectrum calculation section that calculates the product (denoted as a “product frequency spectrum”, which is an example of a second frequency spectrum) of the evaluation index read from the storage section 110 and the FFT frequency spectrum read from the storage section 110. The product frequency spectrum is stored in the storage section 110.

The noise immunity evaluation apparatus 100 further includes a frequency extraction section 150 that extracts, from the product frequency spectrum, a frequency that affects signal transfer in the DUT 300. The noise immunity evaluation apparatus 100 additionally includes a transient analysis section 160 that simulates the signal transfer (performs a transient analysis) on the basis of the extracted frequency. The signal waveform obtained by the transient analysis section 160 is stored in the storage section 110.

In addition, as described in relation to the second exemplary embodiment to be discussed later, the noise immunity evaluation apparatus 100 may further include an estimation section 170 that compares the product frequency spectrum of the DUT 300 and the product frequency spectrum of another DUT 300, and that estimates the superiority or inferiority in noise immunity for the plural DUTs 300.

The storage section 110, the S parameter measurement section 120, and the transient analysis section 160 in FIG. 3 correspond to the MEM 12, the NA 20, and the TA 30 of the computation device 10 in FIG. 2.

The evaluation index calculation section 130, the product frequency spectrum calculation section 140, the frequency extraction section 150, and the estimation section 170 correspond to processes by the program of the CPU 11 in FIG. 2.

In FIG. 3, data are exchanged via the storage section 110. However, data may be exchanged not via the storage section 110.

(Differential Cable 310)

The noise immunity evaluation apparatus 100 and a method of evaluating noise immunity according to the first exemplary embodiment will be described below using a differential cable 310 provided in the electronic device 1 as an example of the DUT 300.

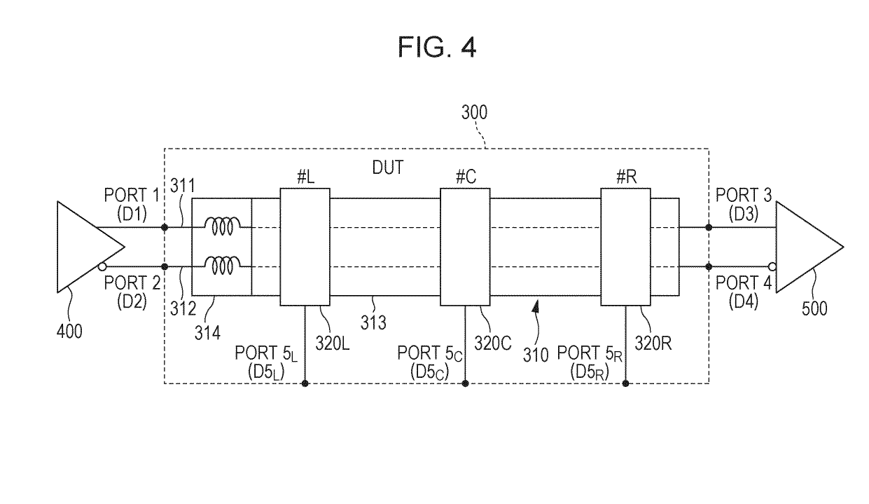

FIG. 4 illustrates the DUT 300 including the differential cable 310. The DUT 300 includes the differential cable 310, and current clamps 320L, 320C, and 320R that allows input of a noise signal (noise) or the like to the differential cable 310 for evaluation of the effect (interaction) of the noise. In FIG. 4, the current clamp 320L is provided at a position (on a side) of the differential cable 310 close to a transmission section 400, the current clamp 320R is provided at a position (on a side) of the differential cable 310 close to a reception section 500, and the current clamp 320C is provided at the center portion of the differential cable 310. However, one current clamp 320 may be provided and moved to each of the positions. Hence, in the case where the current clamps 320L, 320C, and 320R are not differentiated from each other, the current clamps are denoted as the current clamp 320.

The differential cable 310 includes a pair of signal lines 311 and 312, and a sheath portion 313 that surrounds the pair of signal lines 311 and 312. The sheath portion 313 may be a film layer composed of plastic provided to protect and insulate the signal lines 311 and 312, and may further include an electromagnetic shield layer composed of a metal braided wire.

A filter 314 is provided on the side of first end portions of the pair of signal lines 311 and 312. The filter 314 is electrically coupled to the signal lines 311 and 312, cancels an in-phase component of signals transferred through the signal lines 311 and 312, and transmits a differential component of such signals, for example. The filter 314 may not be provided.

In the case where the differential cable 310 includes the filter 314, the differential cable 310 is not symmetric between the transmission section 400 and the reception section 500. Hence, in order to evaluate the effect of noise on the differential cable 310, it is required to at least provide, on the differential cable 310, the current clamps 320L, 320C, and 320R on the side close to the transmission section 400 (transmission section side), at the center portion, and on the side close to the reception section 500 (reception section side), respectively, and evaluate the effect of noise on the differential cable 310.

A port 1 and a port 2 are provided at the first end portions of the pair of signal lines 311 and 312 of the differential cable 310, and connected to the transmission section 400. A port 3 and a port 4 are provided at second end portions of the pair of signal lines 311 and 312, and connected to the reception section 500. That is, the differential cable 310 is provided between the transmission section 400 and the reception section 500. A differential signal transmitted from the transmission section 400 to the port 1 and the port 2, which are examples of an input signal port, propagates through the pair of signal lines 311 and 312, and is received by the reception section 500 from the port 3 and the port 4, which are examples of an output signal port. That is, signals are transferred from the port 1 and the port 2 to the port 3 and the port 4 (signal transfer).

In addition, the current clamps 320L, 320C, and 320R are connected to ports 5_{L}, 5_{C}, and 5_{R}, respectively, which are connected to a noise generation source (not illustrated). In the case where one current clamp 320 is provided and moved to be used as the current clamps 320L, 320C, and 320R, the ports 5_{L}, 5_{C}, and 5_{R} are replaced with one port 5. Hence, in the case where the ports 5_{L}, 5_{C}, and 5_{R} are not differentiated from each other, the ports are denoted as the port 5. The port 5 is an example of a noise signal port.

The DUT 300 illustrated in FIG. 4 is a circuit with five ports for each of the current clamps 320L, 320C, and 320R.

A connector is provided for each of the ports 1 to 5 in order to facilitate connection. The connector allows connection with a connector provided to a device, a cable for connection (connection cable), a measuring instrument, or the like.

The term “port” is widely used for terminals of the DUT 300 used for input and output of signals, and also widely used for terminals of the NA 20 used for input and output of signals.

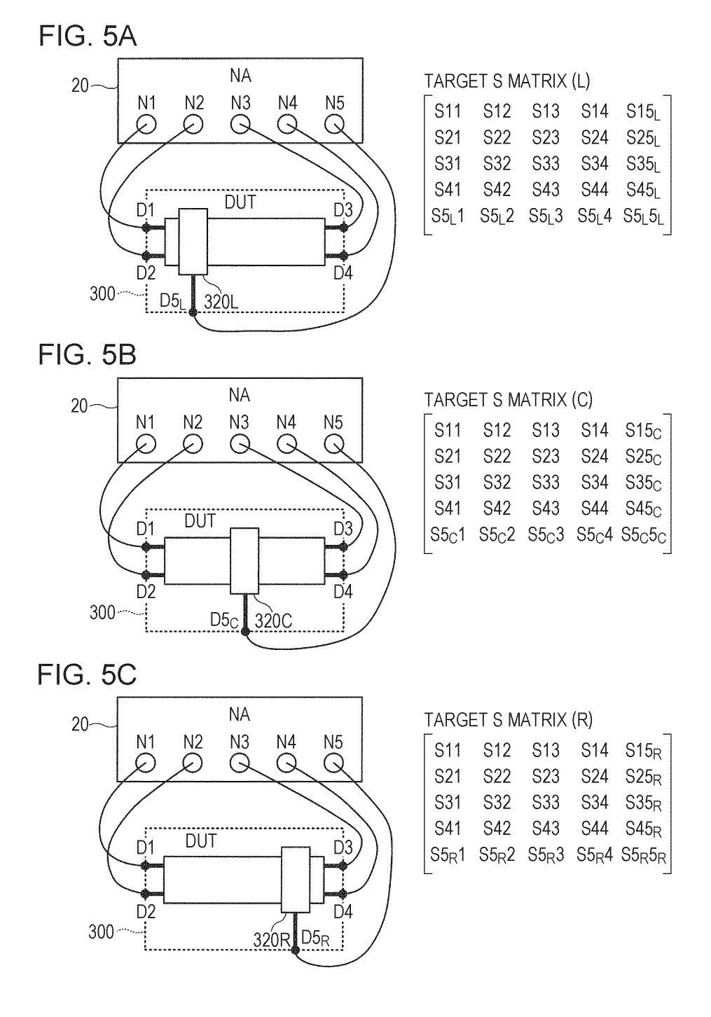

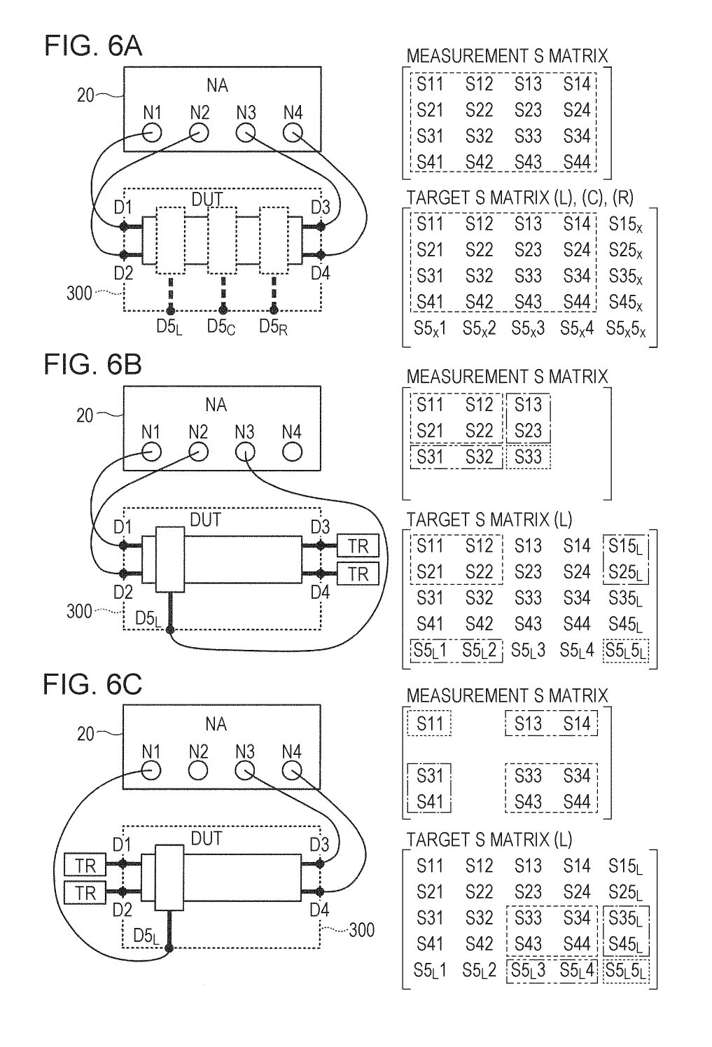

Thus, in order to differentiate between the ports of the DUT 300 and the ports of the NA 20, the ports 1 to 5 of the DUT 300 are denoted as ports D1 to D5 as illustrated in FIG. 4. The ports of the NA 20 are denoted as ports N1 to N5 in the case where the NA 20 includes five ports (ports 1 to 5) as illustrated in FIGS. 5A to 5C to be discussed later, and denoted as ports N1 to N4 in the case where the NA 20 includes four ports (ports 1 to 4) as illustrated in FIGS. 6A to 6C, 7A and 7B, and 8A and 8B to be discussed later.

(Measurement of S Matrix)

FIGS. 5A to 5C each illustrate a connection diagram and an S matrix for a case where an S matrix for the DUT 300 with five ports is measured using the NA 20 with five ports. FIG. 5A corresponds to a case where the current clamp 320L is provided at a position of the differential cable 310 close to the transmission section 400. FIG. 5B corresponds to a case where the current clamp 320C is provided at the center portion of the differential cable 310. FIG. 5C corresponds to a case where the current clamp 320R is provided at a position of the differential cable 310 close to the reception section 500.

The S matrix measured in FIGS. 5A to 5C is an S matrix desired to be obtained (targeted), and thus denoted as a “target S matrix”, and denoted as a “target S matrix (L)”, a “target S matrix (C)”, and a “target S matrix (R)” for the positions of the current clamps 320.

In the case where the target S matrix (L) for the current clamp 320L illustrated in FIG. 5A is to be measured, the target S matrix (L) is measured for the port D5_{L} of the DUT 300. Because a letter “L” has been added to the port, the index of the S parameters is denoted as “5_{L}”.

In the case where the target S matrix (C) for the current clamp 320C illustrated in FIG. 5B is to be measured, the target S matrix (C) is measured for the port D5_{C} of the DUT 300. Because a letter “C” has been added to the port, the index of the S parameters is denoted as “5_{C}”.

In the case where the target S matrix (R) for the current clamp 320R illustrated in FIG. 5C is to be measured, the target S matrix (R) is measured for the port D5_{R} of the DUT 300. Because a letter “R” has been added to the port, the index of the S parameters is denoted as “5_{R}”.

In the case where the DUT 300 with five ports is measured using the NA 20 with five ports as described above, the numbers of ports coincide with each other. Thus, the ports D1 to D5 of the DUT 300 may be connected to the ports N1 to N5 of the NA 20. Hence, it is only necessary to measure the target S matrix (L), the target S matrix (C), and the target S matrix (R) once each, which results in three measurements.

In the case where the current clamps 320 are not provided in FIG. 4, however, the differential cable 310 has four ports, and may be evaluated using a network analyzer with four ports. Hence, network analyzers with four ports or less are widely available. Meanwhile, network analyzers with five ports or more are expensive.

Network analyzers, S matrices, and S parameters as elements of the S matrixes are widely used to evaluate high-frequency circuits, and thus will not be described in detail.

Next, a method of evaluating the DUT 300 with five ports illustrated in FIG. 4 using the NA 20 with four ports will be described.

In the case where the target S matrix (L), the target S matrix (C), and the target S matrix (R) of the DUT 300 with five ports are measured using the NA 20 with four ports, it is necessary to repeat a measurement plural times for each of the target S matrix (L), the target S matrix (C), and the target S matrix (R). Here, the S matrix to be measured using the NA 20 with four ports is denoted as a “measurement S matrix”. Indices (such as 1, 1 in S11) of the S parameters of the measurement S matrix correspond to the numbers of the ports N1 to N4 of the NA 20.

FIGS. 6A to 6C each illustrate a connection diagram, a measurement S matrix, and a target S matrix (L) for a case where a target S matrix (L) is measured using the NA 20 with four ports. FIG. 6A corresponds to a measurement 1. FIG. 6B corresponds to a measurement 2. FIG. 6C corresponds to a measurement 3. The target S matrix (L) is measured in three steps of the measurements 1 to 3. In FIGS. 6A, 6B, and 6C, the connection diagram is illustrated on the left side, and the corresponding measurement S matrix and target S matrix (L) are illustrated on the right side.

In the measurement 1, as illustrated in the connection diagram of FIG. 6A, the ports D1, D2, D3, and D4 of the DUT 300 are connected to the ports N1 to N4 of the NA 20. The port D5_{L} of the DUT 300 (the same applies to the ports D5_{C} and D5_{R}) is not connected to any of the ports N1 to N4 of the NA 20.

In this case, a measurement S matrix with four columns and four rows is obtained.

In the measurement 1, the numbers 1 to 4 of the ports D1 to D4 of the DUT 300 coincide with the numbers 1 to 4 of the ports N1 to N4 of the NA 20. Hence, as indicated as surrounded by broken lines, S11 to S44 of the measurement S matrix resulting from the measurement 1 correspond to S11 to S44, respectively, in the four columns and the four rows of the target S matrix.

Because the S parameters related to the port 5 are not measured, the measurement S matrix is common to the target S matrix (L), the target S matrix (C), and the target S matrix (R). Hence, in the target S matrix, the index of the S parameters is denoted as “5ₓ”.

Some of the S parameters in the target S matrix (L) (the same applies to the target S matrix (C) and the target S matrix (R)) are obtained as a result of the measurement 1.

In the measurement 2, as illustrated in the connection diagram of FIG. 6B, a terminal element TR is attached to each of the ports D3 and D4 of the DUT 300, and the port D5 is connected to the port N3 of the NA 20. The ports D1 and D2 of the DUT 300 are connected to the ports N1 and N2, respectively, of the NA 20 as in the measurement 1.

In this case, a measurement S matrix with three columns and three rows is obtained.

In the measurement 2, the numbers 1 and 2 of the ports D1 and D2 of the DUT 300 coincide with the numbers 1 and 2 of the ports N1 and N2 of the NA 20. Hence, as indicated as surrounded by broken lines, S11, S12, S21, and S22 of the measurement S matrix correspond to S11, S12, S21, and S22, respectively, of the target S matrix. Since the port D5_{L} of the DUT 300 is connected to the port N3 of the NA 20, meanwhile, the number 3 of the measurement S matrix corresponds to the number 5_{L} of the target S matrix. Hence, S13 and S23 of the measurement S matrix correspond to S15_{L} and S25_{L}, respectively, of the target S matrix as indicated as surrounded by dot-and-dash lines, and S31 and S32 of the measurement S matrix correspond to S5_{L}1 and S5_{L}2, respectively, of the target S matrix as indicated as surrounded by double-dashed lines. Further, as indicated as surrounded by dotted lines, S33 of the measurement S matrix corresponds to S5_{L}5_{L} of the target S matrix.

In this way, some of the S parameters of the target S matrix (L) that are not obtained in the measurement 1 are obtained in the measurement 2.

The terminal elements TR are also called terminal resistors, and have a resistance of 50Ω for common network analyzers.

In the measurement 3, as illustrated in the connection diagram of FIG. 6C, a terminal element TR is attached to each of the ports D1 and D2 of the DUT 300, and the port D5 is connected to the port N1 of the NA 20. The ports D3 and D4 of the DUT 300 are connected to the ports N3 and N4, respectively, of the NA 20.

In this case, a measurement S matrix with three columns and three rows is obtained.

In the measurement 3, the numbers 3 and 4 of the ports D3 and D4 of the DUT 300 coincide with the numbers 3 and 4 of the ports N3 and N4 of the NA 20. Hence, as indicated as surrounded by broken lines, S33, S34, S43, and S44 of the measurement S matrix correspond to S33, S34, S43, and S44, respectively, of the target S matrix (L). Since the port D5_{L} of the DUT 300 is connected to the port N1 of the NA 20, meanwhile, the number 1 of the measurement S matrix corresponds to the number 5₁, of the target S matrix (L). Hence, S31 and S41 of the measurement S matrix correspond to S35_{L} and S45_{L}, respectively, of the target S matrix (L) as indicated as surrounded by dot-and-dash lines, and S13 and S14 of the measurement S matrix correspond to S5_{L}3 and S5_{L}4, respectively, of the target S matrix (L) as indicated as surrounded by double-dashed lines. Further, as indicated as surrounded by dotted lines, S11 of the measurement S matrix corresponds to S5_{L}5_{L} of the target S matrix (L).

The remaining S parameters of the target S matrix (L) that are not obtained in the measurements 1 and 2 are obtained in the measurement 3.

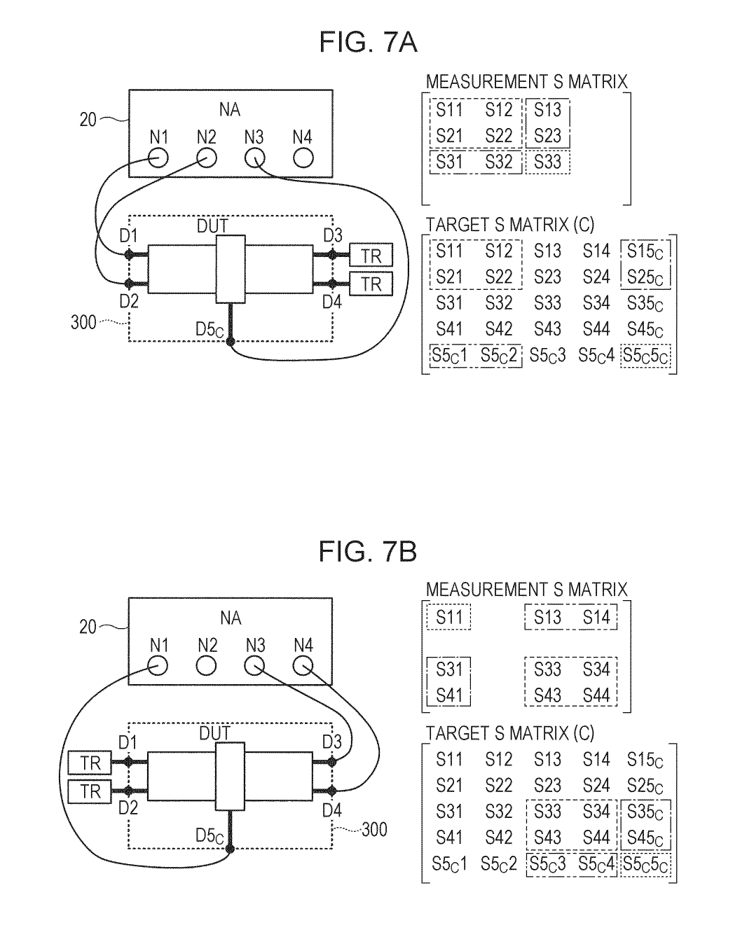

FIGS. 7A and 7B each illustrate a connection diagram, a measurement S matrix, and a target S matrix (C) for a case where a target S matrix (C) is measured using the NA 20 with four ports. FIG. 7A corresponds to a measurement 2. FIG. 7B corresponds to a measurement 3. That is, the target S matrix (C) is measured in two steps of the measurements 2 and 3. This is because the measurement 1 in the target S matrix (L) is common to the target S matrix (C) as described in relation to FIG. 6A. The relationship between the connection diagram, the measurement S matrix, and the target S matrix (C) is the same as that in FIGS. 6B and 6C.

The measurement 2 illustrated in FIG. 7A is the same as the target S matrix (L) illustrated in FIG. 6B, and thus will not be described.

In addition, the measurement 3 illustrated in FIG. 7B is the same as the target S matrix (L) illustrated in FIG. 6C, and thus will not be described.

In FIGS. 7A and 7B, the index of the S parameters in the target S matrix (C) is denoted as “5_{C}”.

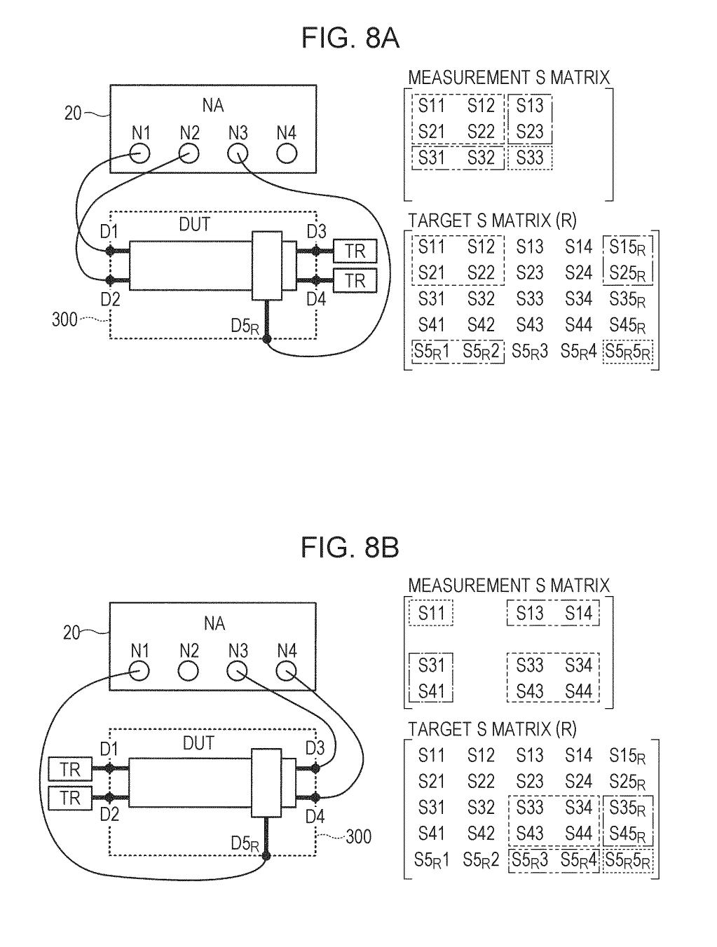

FIGS. 8A and 8B each illustrate a connection diagram, a measurement S matrix, and a target S matrix (R) for a case where a target S matrix (R) is measured using the NA 20 with four ports. FIG. 8A corresponds to a measurement 2. FIG. 8B corresponds to a measurement 3. That is, the target S matrix (R) is measured in two steps of the measurements 2 and 3. This is because the measurement 1 in the target S matrix (L) is common to the target S matrix (R) as described in relation to FIG. 6A. The relationship between the connection diagram, the measurement S matrix, and the target S matrix (R) is the same as that in FIGS. 6B and 6C.

The measurement 2 illustrated in FIG. 8A is the same as the target S matrix (L) illustrated in FIG. 6B, and thus will not be described.

In addition, the measurement 3 illustrated in FIG. 8B is the same as the target S matrix (L) illustrated in FIG. 6C, and thus will not be described.

In FIGS. 8A and 8B, the index of the S parameters in the target S matrix (R) is denoted as “5_{R}”.

As has been described above, seven measurements may be performed to obtain a target S matrix (L), a target S matrix (C), and a target S matrix (R) for the DUT 300 with five ports using the NA 20 with four ports.

As illustrated in FIGS. 6A to 6C, 7A and 7B, and 8A and 8B, measurements are performed for each of the current clamps 320L, 320C, and 320R. However, measurements may be performed while moving the position of one current clamp 320 with respect to the differential cable 310.

Consequently, the position at which the differential cable 310 is most susceptible to noise is specified as discussed later by disposing the current clamp 320 on the transmission section 400 side (#L), on the reception section 500 side (#R), and at the center portion (#C) of the differential cable 310, which is not symmetric between the transmission section 400 side and the reception section 500 side, and measuring an S matrix.

(Method of Evaluating Noise Immunity of Differential Cable 310 According to First Exemplary Embodiment)

The method of evaluating the noise immunity of the differential cable 310 according to the first exemplary embodiment will be described next.

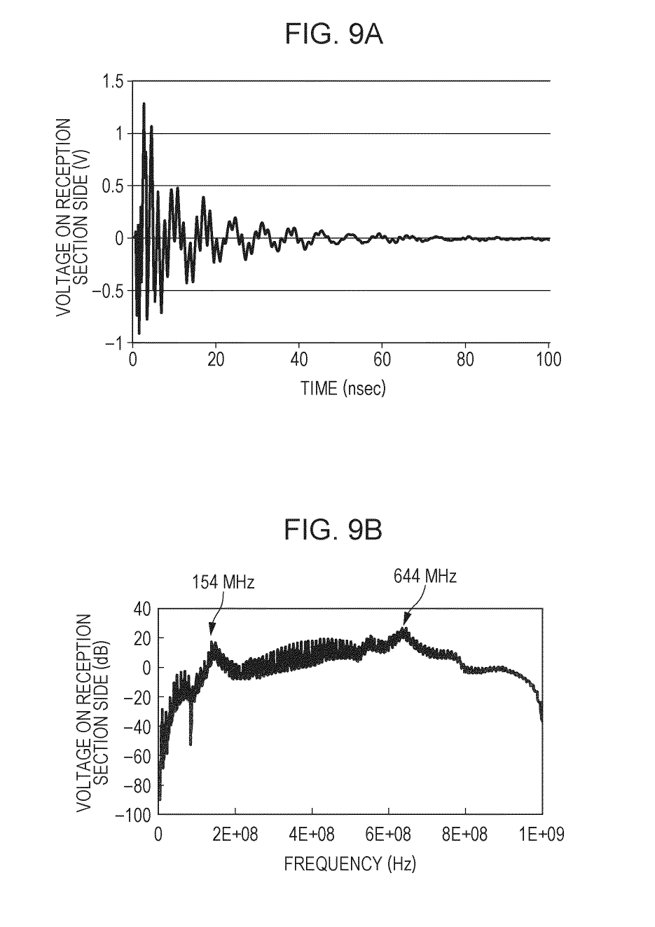

FIG. 9A illustrates a voltage waveform of a voltage induced on the reception section side of the differential cable 310 through discharge by the ESD gun 2. FIG. 9B illustrates an FFT frequency spectrum obtained by performing an FFT on the voltage waveform.

As illustrated in FIG. 9A, when discharge with the current waveform illustrated in FIG. 1B is applied to the outside of the differential cable 310 by the ESD gun 2, a voltage waveform that vibrates between the signal lines 311 and 312 is observed on the reception section 500 side of the differential cable 310. Then, as illustrated in FIG. 9B, an FFT frequency spectrum obtained by performing an FFT on the voltage waveform has voltage peaks (local maximum values) at 154 MHz and 644 MHz.

Hence, it may be determined in an ESD evaluation test that the differential cable 310 is most susceptible to frequencies of 154 MHz and 644 MHz.

It may be considered that an evaluation of the differential cable 310 is obtained by performing a transient analysis, at frequencies corresponding to the voltage peaks (local maximum values), on the FFT frequency spectrum obtained through an electromagnetic field analysis performed using the voltage waveform illustrated in FIG. 1C.

As described below, however, the differential cable 310 may be susceptible to a noise signal at a frequency other than the frequencies corresponding to the voltage peaks (local maximum values) of the FFT frequency spectrum obtained from the electromagnetic field analysis.

A method of obtaining frequencies of noise to which the differential cable 310 is susceptible will be described below. Here, a frequency to which the differential cable 310 is susceptible is obtained from the electromagnetic field analysis and the S parameters.

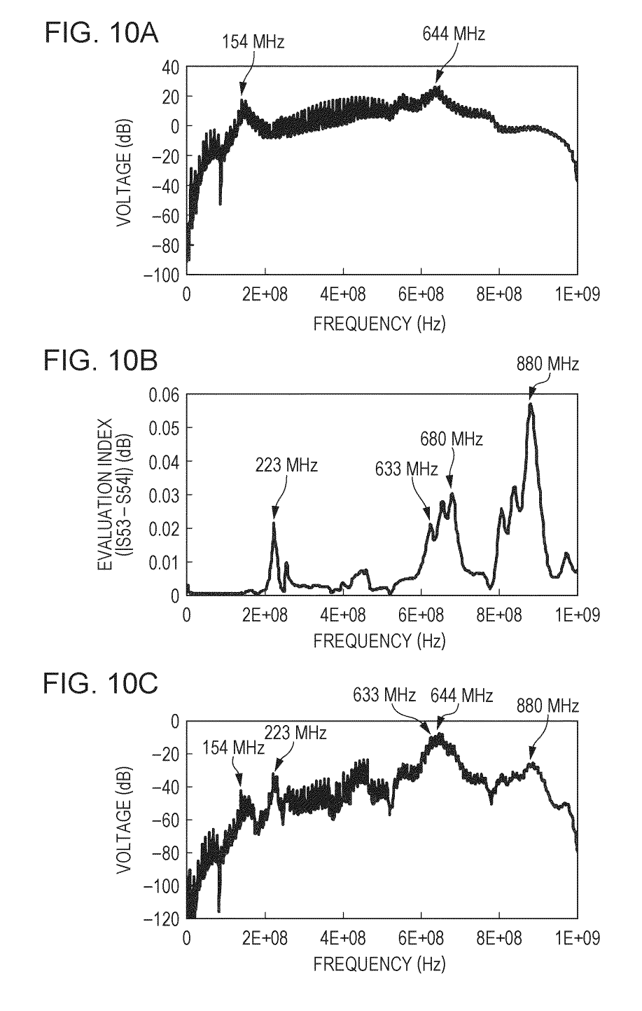

FIGS. 10A to 10C illustrate a method of extracting a frequency at which a transient analysis is performed according to the first exemplary embodiment, the method being applied to a cable A. FIG. 10A illustrates an FFT frequency spectrum obtained through an electromagnetic field analysis, FIG. 10B illustrates an evaluation index (|S53−S54|), and FIG. 10C illustrates a product frequency spectrum which is the product of the FFT frequency spectrum of FIG. 10A and the evaluation index (|S53−S54|) of FIG. 10B.

As seen from FIG. 4, S53 in the S parameters corresponds to a transfer coefficient for transfer from the port D3 on the reception section 500 side to the port D5 of the current clamp 320, and S54 corresponds to a transfer coefficient for transfer from the port D4 on the reception section 500 side to the port D5 of the current clamp 320. That is, S53 and S54 are S parameters that indicate transfer of a signal from the differential cable 310 to the outside (current clamp 320) of the differential cable 310. Meanwhile, S35 and S45 are considered as S parameters that indicate transfer of a signal from the outside (current clamp 320) of the differential cable 310 to the differential cable 310. In general, S53 is often equivalent to S35, and S54 is often equivalent to S45. Therefore, for convenience of description, S53 and S54 are used as parameters that indicate the magnitude of the effect of noise from the outside.

Then, the magnitude of the effect of noise that appears between the pair of signal lines 311 and 312 is seen by obtaining the evaluation index (|S53−S54|). That is, as the evaluation index (|S53−S54|) is larger, the effect of noise that appears on the reception section 500 side is larger.

In the case where the evaluation index (|S51−S52|) for the ports D1 and D2 on the transmission section 400 side is larger than the evaluation index (|S53−S54|), the evaluation index (|S51−S52|) may be used in place of the evaluation index (|S53−S54|).

That is, an evaluation index may be extracted for one of the transmission section 400 side and the reception section 500 side on which the effect of noise is more likely to appear.

Further, in the case where there are different S parameters in which the order of indices is reversed such as (|S53−S54|) and (|S35−S45|), (|S35−S45|) may be used in consideration of the original purpose.

The FFT frequency spectrum illustrated in FIG. 10A has voltage peaks at 154 MHz and 644 MHz.

Meanwhile, the evaluation index (|S53−S54|) illustrated in FIG. 10B has peaks at 223 MHz, 680 MHz, and 880 MHz.

Then, as illustrated in FIG. 10C, a product frequency spectrum, which is the product of the FFT frequency spectrum of FIG. 10A and the evaluation index (|S53−S54|) of FIG. 10B, has voltage peaks (local maximum values) at 154 MHz, 223 MHz, 644 MHz, and 880 MHz.

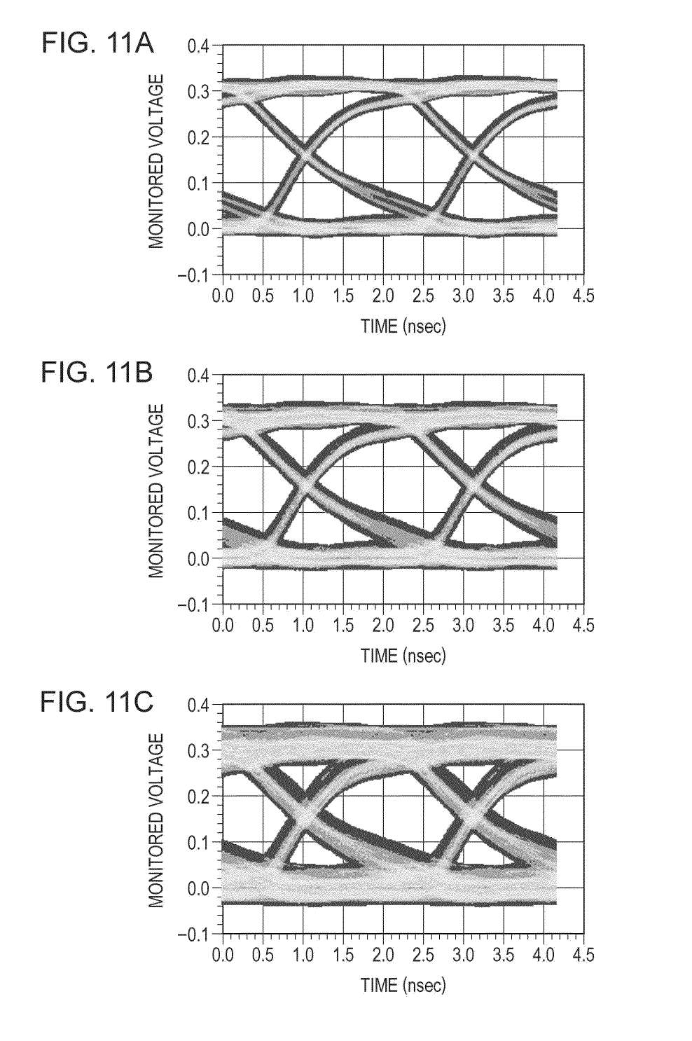

FIGS. 11A to 11C each illustrate an eye pattern, at the reception section 500, of a signal obtained through a transient analysis at 154 MHz for the cable A. The horizontal axis represents the time (nsec), and the vertical axis represents the monitor voltage at the reception section 500. FIG. 11A corresponds to a noise signal voltage of 5 V. FIG. 11B corresponds to a noise signal voltage of 10 V. FIG. 11C corresponds to a noise signal voltage of 20 V. The noise signal voltage is a peak-to-peak (p-to-p) voltage of a sinusoidal wave input to the port D5 of the current clamp 320.

154 MHz is a frequency at which a voltage peak (local maximum value) appears in the electromagnetic field analysis illustrated in FIG. 10A.

Eye openings become smaller as the voltage becomes higher, but are not collapsed even at a noise signal voltage of 20 V.

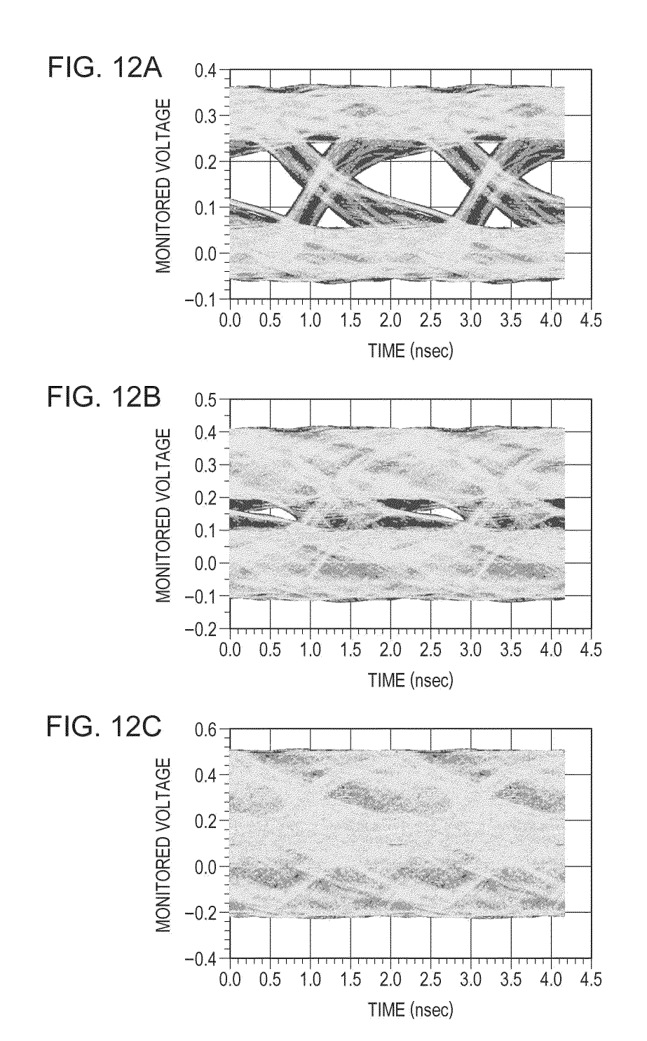

FIGS. 12A to 12C each illustrate an eye pattern, at the reception section 500, of a signal obtained through a transient analysis at 223 MHz for the cable A. FIG. 12A corresponds to a noise signal voltage of 5 V. FIG. 12B corresponds to a noise signal voltage of 10 V. FIG. 12C corresponds to a noise signal voltage of 20 V. The horizontal axis, the vertical axis, and the noise signal voltage are the same as those in FIGS. 11A to 11C.

223 MHz is a frequency at which the evaluation index (|S53−S54|) indicated in FIG. 10B is large.

Eye openings are small at a noise signal voltage of 5 V, and collapsed at noise signal voltages of 10 V and 20 V.

That is, 233 MHz is a frequency at which a voltage peak (local maximum value) does not appear in the FFT frequency spectrum obtained through the electromagnetic field analysis of FIG. 10A. At the frequency, however, it is seen that the cable A is more affected than at 154 MHz at which a voltage peak (local maximum value) appears in the electromagnetic field analysis.

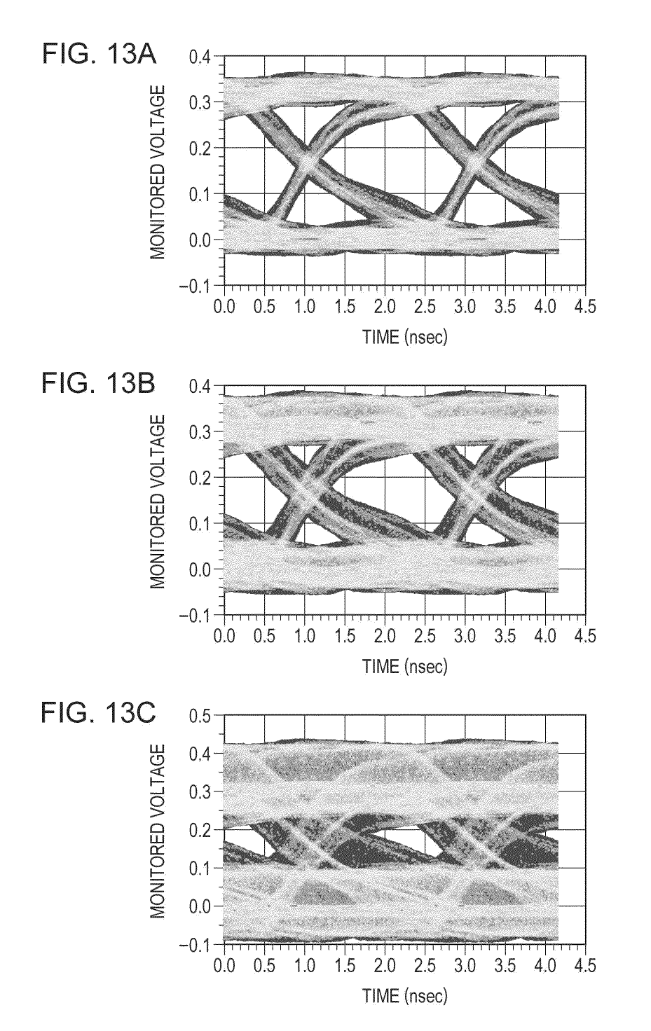

FIGS. 13A to 13C each illustrate an eye pattern, at the reception section 500, of a signal obtained through a transient analysis at 633 MHz for the cable A. FIG. 13A corresponds to a noise signal voltage of 5 V. FIG. 13B corresponds to a noise signal voltage of 10 V. FIG. 13C corresponds to a noise signal voltage of 20 V. The horizontal axis, the vertical axis, and the noise signal voltage are the same as those in FIGS. 11A to 11C.

633 MHz is a frequency at which a large difference between the S parameters indicated in FIG. 10B appears.

Eye openings have already become small at a noise signal voltage of 5 V, and have become even smaller at noise signal voltages of 10 V and 20 V.

That is, 633 MHz is also a frequency at which a voltage peak (local maximum value) does not appear in the FFT frequency spectrum obtained through the electromagnetic field analysis of FIG. 10A. At the frequency, however, it is seen that the cable A is more affected than at 154 MHz at which a voltage peak appears in the electromagnetic field analysis.

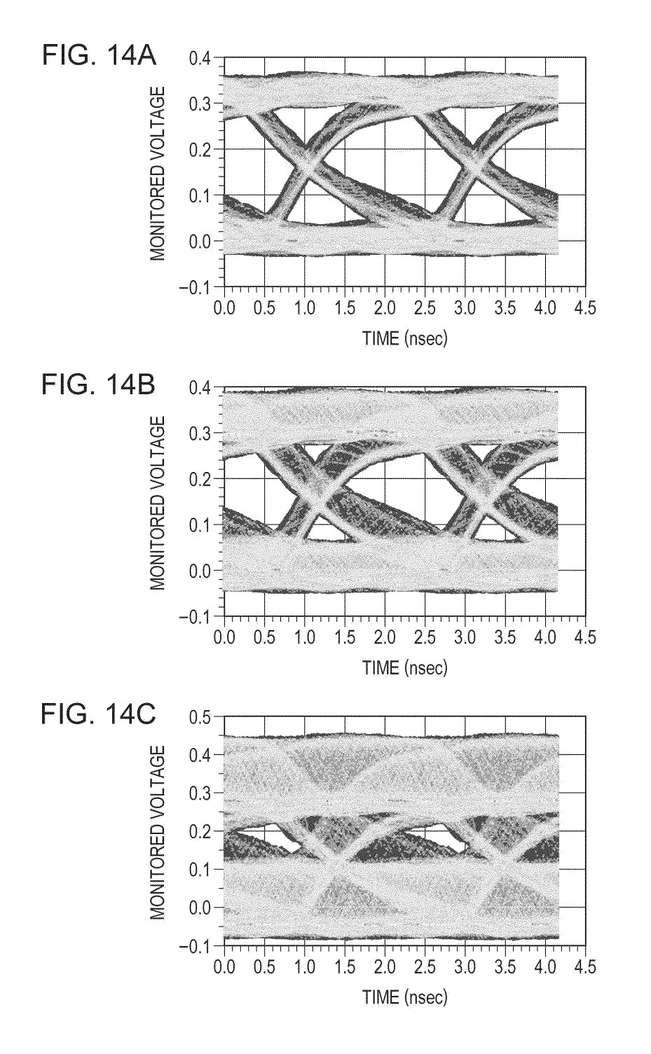

FIGS. 14A to 14C each illustrate an eye pattern, at the reception section 500, of a signal obtained through a transient analysis at 644 MHz for the cable A. FIG. 14A corresponds to a noise signal voltage of 5 V. FIG. 14B corresponds to a noise signal voltage of 10 V. FIG. 14C corresponds to a noise signal voltage of 20 V. The horizontal axis, the vertical axis, and the noise signal voltage are the same as those in FIGS. 11A to 11C.

644 MHz is a frequency at which a voltage peak appears in the electromagnetic field analysis illustrated in FIG. 10A.

Eye openings have already become small at a noise signal voltage of 5 V, and have become even smaller at noise signal voltages of 10 V and 20 V.

That is, 644 MHz is a frequency at which a voltage peak appears in the FFT frequency spectrum obtained through the electromagnetic field analysis of FIG. 10A. At the frequency, however, it is seen that the cable A is less affected than at 223 MHz at which a voltage peak (local maximum value) appears in the evaluation index (|S53−S54|) indicated in FIG. 10B.

As a result of the transient analysis, as has been described above, the eyes are most collapsed at a frequency of 223 MHz at which a voltage peak (local maximum value) appears in the evaluation index (|S53−S54|) of FIG. 10B.

That is, if frequencies are extracted only through an electromagnetic field analysis and a transient analysis is performed at the extracted frequencies to evaluate the differential cable 310, 223 MHz at which an adverse effect appears may not be extracted. Therefore, the method of extracting frequencies using voltage peaks (local maximum values) in an FFT frequency spectrum obtained through an electromagnetic field analysis is not good enough to extract frequencies at which a transient analysis is performed in order to evaluate the differential cable 310.

Hence, in the first exemplary embodiment, frequencies at which the differential cable 310 is evaluated are extracted using the product frequency spectrum which is the product of the FFT frequency spectrum obtained through the electromagnetic field analysis and the evaluation index (|S53−S54|).

The frequencies at which the differential cable 310 is evaluated may be frequencies at which a voltage peak (local maximum value) that is equal to or more than a threshold, for example −40 dB, set for the product frequency spectrum indicated in FIG. 10C appears, for example. In this way, frequencies at which a transient analysis is performed in order to evaluate the differential cable 310 are extracted by a program in the noise immunity evaluation apparatus 100.

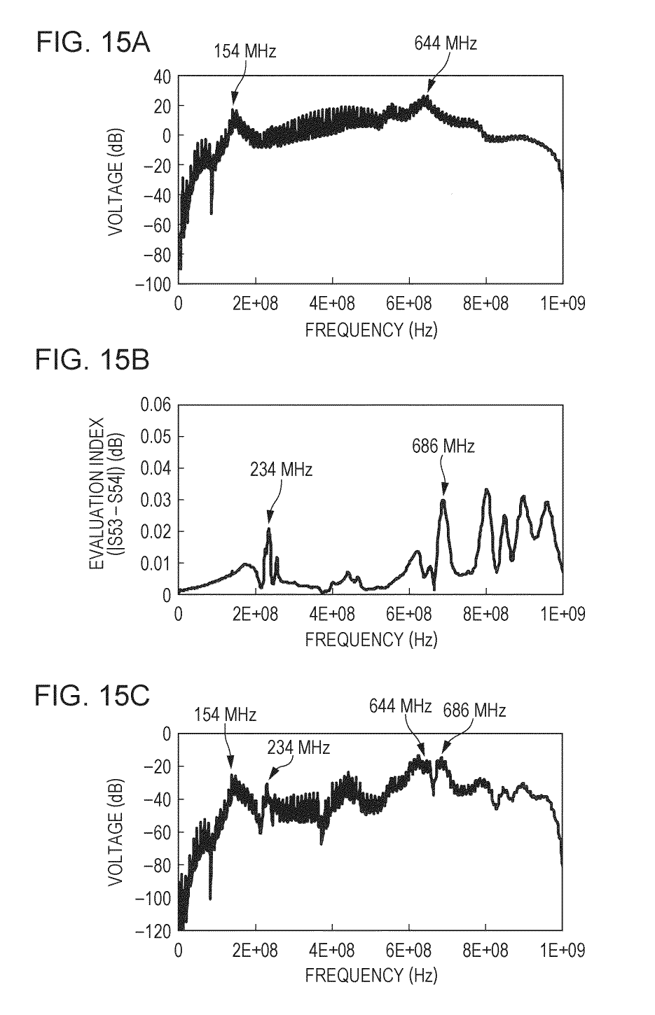

FIGS. 15A to 15C illustrate a method of extracting a frequency at which a transient analysis is performed according to the first exemplary embodiment, the method being applied to a cable B. FIG. 15A illustrates an FFT frequency spectrum obtained through an electromagnetic field analysis, FIG. 15B illustrates an evaluation index (|S53−S54|), and FIG. 15C illustrates a product frequency spectrum which is the product of the FFT frequency spectrum of FIG. 15A and the evaluation index (|S53−S54|) of FIG. 15B. The drawings are similar to FIGS. 10A to 10C, and thus will not be described in detail.

As illustrated in FIG. 15A, the FFT frequency spectrum has voltage peaks at 154 MHz and 644 MHz.

As illustrated in FIG. 15B, the evaluation index (|S53 S54|) has peaks at 234 MHz and 686 MHz.

As illustrated in FIG. 15C, a product frequency spectrum, which is the product of the FFT frequency spectrum and the evaluation index (|S53−S54|), also has voltage peaks at 234 MHz and 686 MHz in addition to 154 MHz and 644 MHz.

In this way, frequencies that affect the differential cable 310 are extracted using the product frequency spectrum obtained by multiplying the FFT frequency spectrum by the evaluation index (|S53−S54|).

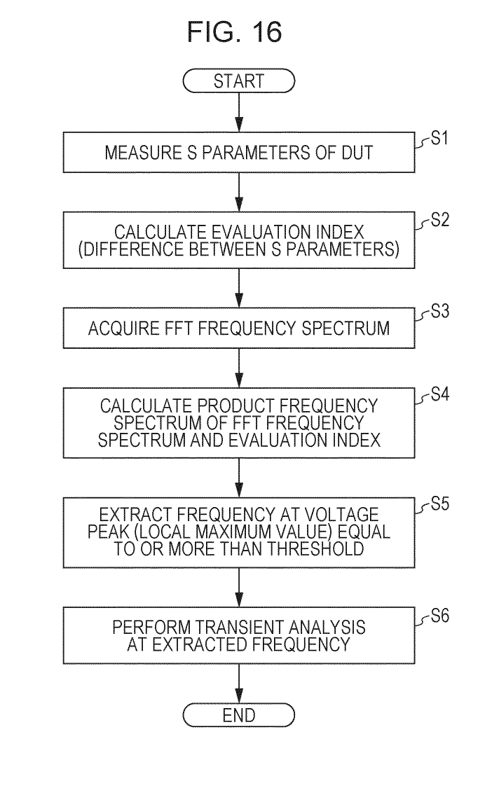

FIG. 16 is a flowchart of a method of evaluating noise immunity according to the first exemplary embodiment.

Here, a description will be made using the functional blocks of the noise immunity evaluation apparatus 100 illustrated in FIG. 3.

The S parameter measurement section 120 measures an S matrix for the DUT 300 (step 1, which is denoted as “S1” in FIG. 16; the same applies hereinafter) (S parameter measurement step).

Next, the evaluation index calculation section 130 calculates a difference (evaluation index) between S parameters that indicates the transfer characteristics between the noise signal port (for example, the port 5) and the output signal port in the S matrix (step 2) (evaluation index calculation step).

Then, an FFT frequency spectrum is acquired from the EMFA 200 (step 3).

Subsequently, the product frequency spectrum calculation section 140 calculates a product frequency spectrum which is the product of the evaluation index and the FFT frequency spectrum (step 4) (product frequency spectrum calculation step, which is an example of a second frequency spectrum calculation step).

Next, the frequency extraction section 150 extracts a frequency at which a voltage peak (local maximum value) that is higher than a threshold determined in advance appears as a frequency at which a transient analysis is performed (step 5) (frequency extraction step).

Then, the transient analysis section 160 performs a transient analysis using a noise signal at the extracted frequency (step 6).

Evaluation of the noise immunity of the differential cable 310 is thus ended.

### Second Exemplary Embodiment

In the first exemplary embodiment, a frequency at which a voltage peak (local maximum value) that is higher than a threshold determined in advance appears is extracted, and a transient analysis is performed at the extracted frequency to evaluate noise immunity.

Here, a method of evaluating the noise immunity of the differential cable 310 using a value obtained from the product frequency spectrum will be described.

The description here is also made using the cable A and the cable B.

As a result of performing an ESD immunity test using the ESD gun 2, the cable A exhibits poorer results than those exhibited by the cable B. That is, it is determined in the ESD immunity test that the cable B is better than the cable A.

(Method of Evaluating Noise Immunity of Differential Cable 310 According to Second Exemplary Embodiment)

First, signal waveforms obtained through a transient analysis at 154 MHz and 644 MHz for the cable B will be described. 154 MHz and 644 MHz are frequencies at which a voltage peak (local maximum value) appears in the electromagnetic field analysis. The signal waveforms obtained through a transient analysis at 154 MHz and 644 MHz for the cable A are illustrated in FIGS. 11A to 11C and 14A to 14C, respectively.

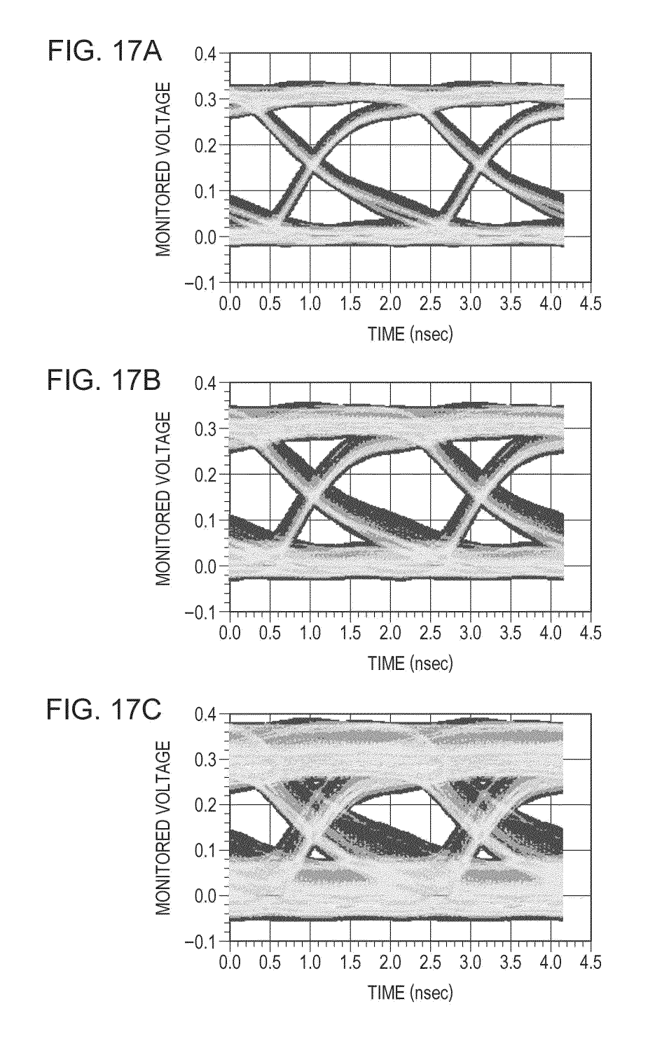

FIGS. 17A to 17C each illustrate an eye pattern, at the reception section 500, of a signal obtained through a transient analysis at 154 MHz for the cable B. FIG. 17A corresponds to a noise signal voltage of 5 V. FIG. 17B corresponds to a noise signal voltage of 10 V. FIG. 17C corresponds to a noise signal voltage of 20 V. The noise signal voltage etc. are the same as those in FIGS. 11A to 11C.

Eye openings become smaller as the noise signal voltage becomes higher, but are not collapsed even at a noise signal voltage of 20 V.

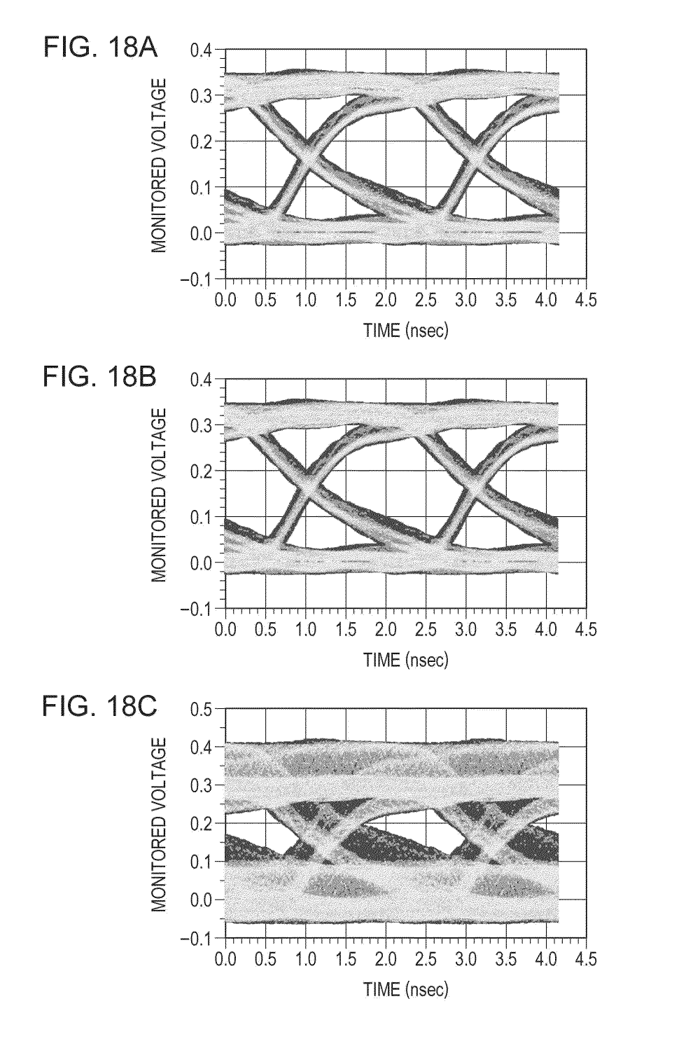

FIGS. 18A to 18C each illustrate an eye pattern, at the reception section 500, of a signal obtained through a transient analysis at 644 MHz for the cable B. FIG. 18A corresponds to a noise signal voltage of 5 V. FIG. 18B corresponds to a noise signal voltage of 10 V. FIG. 18C corresponds to a noise signal voltage of 20 V. The noise signal voltage etc. are the same as those in FIGS. 11A to 11C.

Eye openings become smaller as the noise signal voltage becomes higher, but are not collapsed even at a noise signal voltage of 20 V.

Here, the eye patterns for the cable A and the cable B will be compared.

When the eye patterns for the cable A (FIGS. 11A to 11C) and the cable B (FIGS. 17A to 17C) at 154 MHz are compared, the eye openings at a noise signal voltage 20 V for the cable A are larger. That is, it is determined that the cable A has better characteristics at 154 MHz than those of the cable B.

When the eye patterns for the cable A (FIGS. 14A to 14C) and the cable B (FIGS. 18A to 18C) at 644 MHz are compared, meanwhile, the eye openings for the cable B are larger. That is, it is determined that the cable B has better characteristics at 644 MHz than those of the cable A.

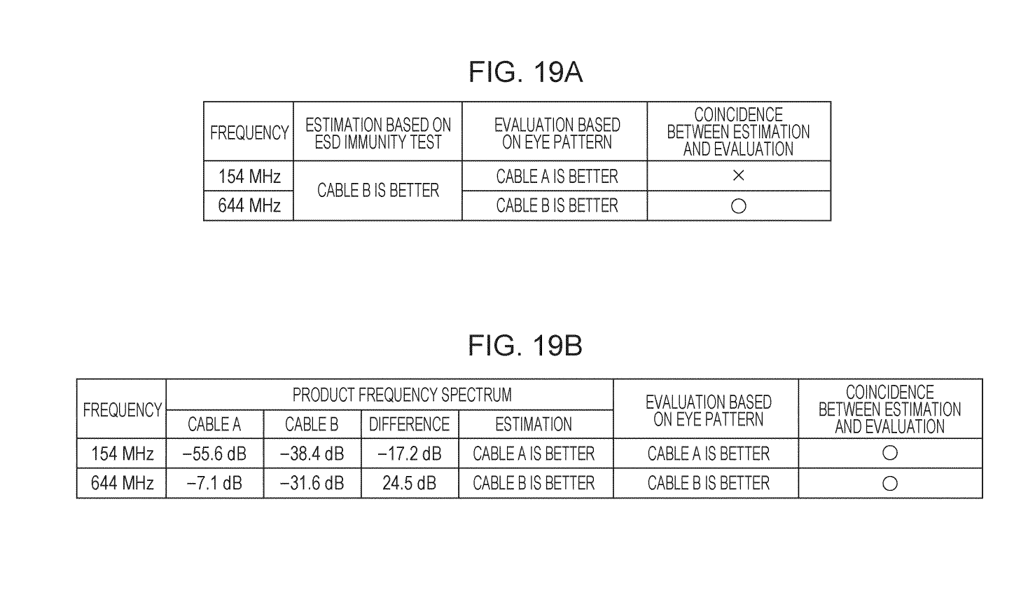

FIGS. 19A and 19B illustrate estimations based on ESD immunity tests, evaluations based on eye patterns, estimations based on product frequency spectra, and coincidence between the estimations and the evaluations. FIG. 19A illustrates estimations based on ESD immunity tests, evaluations based on eye patterns, and coincidence between the estimations and the evaluations. FIG. 19B illustrates estimations based on product frequency spectra, evaluations based on eye patterns, and coincidence between the estimations and the evaluations. For coincidence between the estimations and the evaluations, a coincidence is indicated by a circular mark, and a non-coincidence is indicated by a cross mark.

As illustrated in FIG. 19A, it is estimated that “the cable B is better” in the ESD immunity test, but it is determined on the basis of the eye pattern at 154 MHz that “the cable A is better”, which does not coincide with the estimation. On the other hand, it is determined on the basis of the eye pattern at 644 MHz that “the cable B is better”, which coincides with the estimation. That is, the estimation based on the ESD immunity test and the evaluation based on the eye pattern may not coincide with each other.

In FIG. 19B, meanwhile, the differential cable 310 is evaluated using a product frequency spectrum without performing a transient analysis.

First, voltages (negative dB values) at 154 MHz and 644 MHz are obtained in the product frequency spectrum. Then, a difference is calculated by subtracting the value for the cable B from the value for the cable A. In the case where the difference is negative, it is estimated that the cable A is better than the cable B. In the case where the difference is positive, it is estimated that the cable B is better than the cable A. This is because the voltage values are represented in negative dB values, and therefore smaller voltage values (larger values on the negative side) mean that the differential cable 310 is less affected by noise from the outside, that is, less susceptible to noise from the port 5.

At 154 MHz, as illustrated in FIG. 19B, the cable A provides a voltage value of −55.6 dB, and the cable B provides a voltage value of −38.4 dB, which results in a difference of −17.2 dB. Hence, it is estimated that the cable A is better. At 644 MHz, meanwhile, the cable A provides a voltage value of −7.1 dB, and the cable B provides a voltage value of −31.6 dB, which results in a difference of −24.5 dB. Hence, it is estimated that the cable B is better. The estimation based on the product frequency spectrum coincides with the evaluation based on the eye pattern.

As has been described above, the superiority or inferiority of the differential cable 310 may be evaluated by estimation based on the voltage (value) of the product frequency spectrum without obtaining an eye pattern through a transient analysis. This method is also effective in the case where plural differential cables 310 are compared.

In the foregoing description, evaluations at 154 MHz and 644 MHz are taken as examples. However, evaluations at other frequencies may also be obtained by comparing the product frequency spectra indicated in FIGS. 10C and 15C.

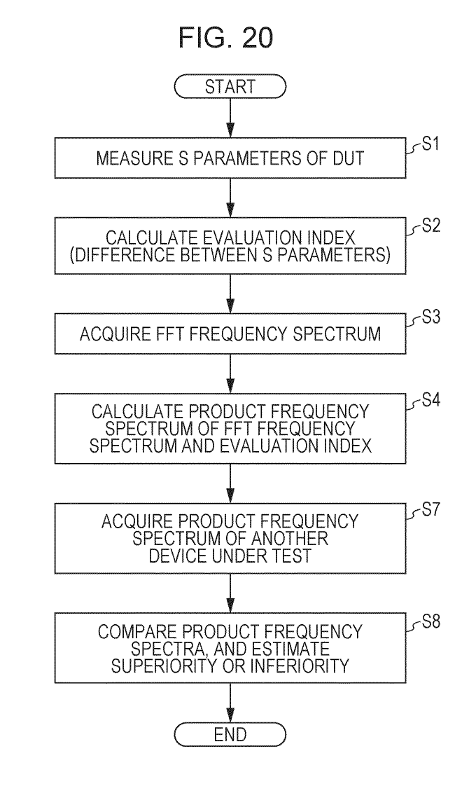

FIG. 20 is a flowchart of a method of evaluating noise immunity according to the second exemplary embodiment. Steps 1 to 4 are the same as those in the flowchart illustrated in FIG. 16. Hence, the same reference numerals are added to omit description.

Next, a product frequency spectrum for another differential cable 310 is acquired (step 7).

Then, the estimation section 170 illustrated in FIG. 3 compares the product frequency spectrum calculated in step 4 and the product frequency spectrum for the other differential cable 310, and estimates the superiority or inferiority of the differential cable 310 by determining that a differential cable 310 with a smaller product frequency spectrum provides better noise immunity (step 8).

In the first exemplary embodiment and the second exemplary embodiment, noise immunity is evaluated for the DUT 300 including the differential cable 310. The first exemplary embodiment and the second exemplary embodiment may also be applied to wiring formed on a substrate.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A noise immunity evaluation apparatus comprising:
an S parameter measurement section that measures S parameters of a device under test that includes at least a pair of input signal ports, a pair of output signal ports, and a noise signal port for input of a noise signal;
an evaluation index calculation section that calculates, as an evaluation index, a difference between S parameters, among the S parameters, between the noise signal port and the pair of input signal ports or a difference between S parameters, among the S parameters, between the noise signal port and the pair of output signal ports;
a second frequency spectrum calculation section that acquires a first frequency spectrum obtained by performing a fast Fourier transform on a voltage waveform obtained by performing an electromagnetic field analysis on the noise signal input to the noise signal port, and that calculates a second frequency spectrum as a product of the first frequency spectrum and the evaluation index; and
a frequency extraction section that extracts a frequency at which a voltage reaches a local maximum value in the second frequency spectrum as a frequency at which noise immunity is evaluated.

2. The noise immunity evaluation apparatus according to claim 1,
wherein the evaluation index calculation section determines, as the evaluation index, a larger one of the difference between the S parameters between the noise signal port and the pair of input signal ports and the difference between the S parameters between the noise signal port and the pair of output signal ports.

3. The noise immunity evaluation apparatus according to claim 1, further comprising:
a transient analysis section that analyzes transient characteristics of a signal from the pair of input signal ports to the pair of output signal ports at the frequency extracted by the frequency extraction section.

4. The noise immunity evaluation apparatus according to claim 1, further comprising:
an electromagnetic field analysis section that obtains the voltage waveform through the electromagnetic field analysis performed on the noise signal input to the noise signal port of the device under test, and that performs a fast Fourier transform on the voltage waveform to calculate the first frequency spectrum.

5. The noise immunity evaluation apparatus according to claim 1, further comprising:
an estimation section that compares the second frequency spectrum obtained for the device under test and a second frequency spectrum obtained for a different device under test, and that estimates superiority or inferiority in noise immunity for the device under test and the different device under test.

6. A method of evaluating noise immunity of a device under test that includes at least a pair of input signal ports, a pair of output signal ports, and a noise signal port for input of a noise signal, the method comprising:
measuring S parameters of the device under test;
calculating, as an evaluation index, a difference between S parameters, among the S parameters, between the noise signal port and the pair of input signal ports or a difference between S parameters between the noise signal port and the pair of output signal ports;
acquiring a first frequency spectrum obtained by performing a fast Fourier transform on a voltage waveform obtained by performing an electromagnetic field analysis on the noise signal input to the noise signal port, and calculating a second frequency spectrum as a product of the first frequency spectrum and the evaluation index; and
extracting a frequency at which a voltage reaches a local maximum value in the second frequency spectrum as a frequency at which noise immunity is evaluated.

7. A non-transitory computer readable medium storing a program causing a computer to execute a process, the process comprising:
acquiring S parameters measured for a device under test that includes at least a pair of input signal ports, a pair of output signal ports, and a noise signal port for input of a noise signal;
calculating, as an evaluation index, a difference between S parameters, among the S parameters, between the noise signal port and the pair of input signal ports or a difference between S parameters between the noise signal port and the pair of output signal ports;
acquiring a first frequency spectrum obtained by performing a fast Fourier transform on a voltage waveform obtained by performing an electromagnetic field analysis on the noise signal input to the noise signal port;
calculating a second frequency spectrum as a product of the first frequency spectrum and the evaluation index; and
extracting a frequency at which a voltage reaches a local maximum value in the second frequency spectrum as a frequency at which noise immunity is evaluated.
